(19) United States
(12) Patent Application Publication
(10) Pub. No.: US 2011/0277816 A1
(43) Pub. Date: Nov. 17, 2011

(54) SOLAR CELL WITH SHADE-FREE FRONT ELECTRODE

(75) Inventors: Zheng Xu, Pleasanton, CA (US); Jianming Fu, Palo Alto, CA (US); Jiunn Benjamin Heng, San Jose, CA (US); Chentao Yu, Sunnyvale, CA (US)

(73) Assignee: SIERRA SOLAR POWER, INC., Fremont, CA (US)

(21) Appl. No.: 13/048,804

(22) Filed: Mar. 15, 2011

Related U.S. Application Data
(60) Provisional application No. 61/333,584, filed on May 11, 2010.

(51) Int. Cl. H01L 31/052; H01L 31/0232; H01L 31/18; H01L 31/0224

(52) U.S. Cl. 136/246; 136/256; 438/72; 257/E31.127

(57) ABSTRACT

One embodiment of the present invention provides a solar cell with shade-free front electrode. The solar cell includes a photovoltaic body, a front-side ohmic contact layer situated above the photovoltaic body, a back-side ohmic contact layer situated below the photovoltaic body, a front-side electrode situated above the front-side ohmic contact layer, and a back-side electrode situated below the back-side ohmic contact layer. The front-side electrode includes a plurality of parallel metal grid lines, and the surface of at least one metal grid line is curved, thereby allowing incident light hitting the curved surface to be reflected downward and absorbed by the solar cell surface adjacent to the metal grid line.

### RELATED APPLICATION

This application claims the benefit of U.S. Provisional Application No. 61/333,584, Attorney Docket Number SSP10-1003PSP, entitled “Solar Cell with Shade-Free Front Electrode and Related Module,” by inventors Zheng Xu, Jianming Fu, Jiunn B. Heng, and Chentao Yu, filed 11 May 2010.

### BACKGROUND

1. Field

This disclosure is generally related to solar cells. More specifically, this disclosure is related to a solar cell having a shade-free front electrode.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

FIG. 1A presents a diagram illustrating an exemplary solar cell (prior art). Solar cell 100 includes an n-type doped Si substrate 102, a p⁺ silicon emitter layer 104, a front electrode grid 106, and an Al back electrode 108. Arrows in FIG. 1A indicate incident sunlight. Front electrode grid 106 often includes a metal grid that is opaque to sunlight, and casts a shadow on the front surface of solar cell 100. For a conventional solar cell, the front electrode grid can block up to 8% of the incident sunlight, thus significantly reducing the conversion efficiency.

Various approaches have been proposed to eliminate or reduce the shading caused by the front electrode grid. U.S. Pat. No. 6,274,402 discloses a photovoltaic device with interdigitated back contact (IBC) to eliminate the front-electrode-grid shading. FIG. 2A presents a diagram illustrating an IBC-based solar cell (prior art). From FIG. 2A, one can see that the p-n junction is formed on the backside of a Si wafer, and both the positive and negative electrodes are disposed on the back surface of a solar cell. As a result, no incident sunlight is blocked on the front surface. However, the IBC-based solar cells require a lengthy and complex process flow, increasing production cost significantly.

U.S. Pat. No. 7,649,141 discloses an emitter-wrap-through (EWT) back-contact solar cell to eliminate the shading effect by the front electrode. FIG. 2B presents a diagram illustrating an EWT back-contact solar cell (prior art). To fabricate an EWT back-contact solar cell, through holes are formed on a Si wafer, and the emitter is formed on the front surface, the sidewall of the through holes, and a pre-defined region near the through holes on the back surface. Similar to the IBC-based solar cell, both electrodes are placed on the backside of the EWT back-contact solar cell. Consequently, no incident light is blocked on the front surface. However, this approach requires forming a large number of through holes on a Si wafer, thus increasing production cost. Moreover, the through holes usually have high series resistance, which reduces the fill factor of the solar cell, thus reducing the conversion efficiency of the solar cell.

U.S. Pat. No. 5,232,519 discloses forming a top encapsulating layer with diffractive grooves above the front electrode grid of a solar cell in order to minimize shading effects otherwise caused by shadows from the grid, as illustrated in FIG. 2C. In this configuration, the groove in the encapsulating layer causes the incident light to be diffracted and bypass the front electrode, thus reducing the shading effect of front electrode. However, this approach requires an additional encapsulating layer and an accurate alignment between the grooves and the front electrode grid, thus increasing production complexity and cost.

U.S. Pat. No. 5,554,299 proposes a similar light directing element in the form of an encapsulating cover above the front electrode grid of a solar cell in order to minimize shading effects otherwise caused by shadows from the grid as illustrated in FIG. 2D. In this configuration, the encapsulating cover fits onto the top of a solar cell. The bottom surface of the encapsulating cover is provided with V-shaped grooves which are in registry with the underlying front electrode grid of the solar cell. The sidewalls of the grooves are coated with a reflective coating, which causes the incident light to be reflected onto portions of the solar cell surface adjacent to the front electrode, thus minimizing shading effects caused by the front electrode grid. However, this approach also requires an additional encapsulating layer and an accurate alignment between the V-grooves and the front electrode grid. In addition, the V-grooves must have reflective coatings. These requirements increase process complexity and production cost.

### SUMMARY

One embodiment of the present invention provides a solar cell with a shade-free front electrode. The solar cell includes a photovoltaic body, a front-side ohmic contact layer situated above the photovoltaic body, a back-side ohmic contact layer situated below the photovoltaic body, a front-side electrode situated above the front-side ohmic contact layer, and a back-side electrode situated below the back-side ohmic contact layer. The front-side electrode includes a plurality of parallel metal grid lines, and the surface of at least one metal grid line is curved, thereby allowing incident light hitting the curved surface to be reflected downward and to be absorbed by the solar cell surface adjacent to the metal grid line.

In a variation on the embodiment, a plane tangent to the curved surface forms an angle with the solar cell surface, and the angle is between 67.5° and 90°.

In a variation on the embodiment, a pitch between the parallel metal grid lines is between 1 mm and 3 mm.

In a variation on the embodiment, a width of the metal grid lines is between 30 μm and 50 μm, and a vertical aspect ratio of the metal grid lines is larger than 2.5.

In a variation on the embodiment, the metal grid lines include silver grid lines, silver-coated or tin-coated copper grid lines.

In a variation on the embodiment, the metal grid lines are formed using one of the following processes: an electroplating process followed by a controlled deplating process, and a photoresist lift-off process.

In a variation on the embodiment, the photovoltaic body includes a base layer that includes crystalline-Si (c-Si) of n-type doped or p-type doped, a front-side passivation layer that includes intrinsic amorphous-Si (a-Si) situated above the base layer, a back-side passivation layer that includes a-Si situated below the base layer, an emitter situated above the front-side passivation layer, and a back surface field (BSF) layer situated below the back-side passivation layer. The emitter and the BSF layer include heavily doped a-Si. The emitter has an opposite doping type of the base layer, and the BSF layer has the same doping type of the base layer.

In a variation on the embodiment, the photovoltaic body includes a base layer that includes crystalline-Si (c-Si) of n-type doped or p-type doped, a front-side quantum tunneling barrier (QTB) layer situated above the base layer, a back-side QTB layer situated below the base layer, an emitter situated above the front-side QTB layer, and a back surface field (BSF) layer situated below the back-side QTB layer. The emitter and the BSF layer include graded doped a-Si. The emitter has an opposite doping type of the base layer, and the BSF layer has the same doping type of the base layer.

In a further variation, the QTB layer includes at least one of: silicon oxide (SiOₓ), hydrogenated SiOₓ, silicon nitride (SiNₓ), hydrogenated SiNₓ, aluminum oxide (AlOx), silicon oxynitride (SiON), and hydrogenated SiON.

In a variation on the embodiment, the front-side ohmic contact layer and/or the back-side ohmic contact layer include transparent conductive oxide (TCO).

### BRIEF DESCRIPTION OF THE FIGURES

FIG. 1 presents a diagram illustrating an exemplary solar cell (prior art).

FIG. 2A presents a diagram illustrating an IBC-based solar cell (prior art).

FIG. 2B presents a diagram illustrating an EWT back-contact solar cell (prior art).

FIG. 2C presents a diagram illustrating an encapsulated solar cell (prior art).

FIG. 2D presents a diagram illustrating an encapsulated solar cell (prior art).

FIG. 3A presents a diagram illustrating a cross-sectional view of an exemplary solar cell that implements front metal electrode grids with curved surfaces, in accordance with an embodiment of the present invention.

FIG. 3B presents a diagram illustrating a magnified view of the cross section of a front electrode grid line in accordance with an embodiment of the present invention.

FIG. 3C presents a diagram illustrating a magnified view of the cross section of a conventional front electrode grid line (prior art).

FIG. 3D presents a diagram illustrating a magnified view of the cross section of a front electrode grid line that does not reduce or eliminate the shading effect.

FIG. 4A presents a diagram illustrating the orientation of a solar panel installed on a rooftop in accordance with an embodiment of the present invention.

FIG. 4B presents a diagram illustrating a sun path chart for locations at 40° North Latitude.

FIG. 5 presents a diagram illustrating incident sunlight reflecting off the curved surface of the grid line to be absorbed by an adjacent solar cell surface in the summer and in the winter, in accordance with an embodiment of the present invention.

FIG. 6A presents a diagram illustrating a solar cell having an Ag-based front electrode grid line in accordance with an embodiment of the present invention.

FIG. 6B presents a diagram illustrating a solar cell having an Ag-coated Cu-based front electrode grid line in accordance with an embodiment of the present invention.

FIG. 7 presents a diagram illustrating the process of fabricating a solar cell with shade-free front electrode in accordance with an embodiment of the present invention.

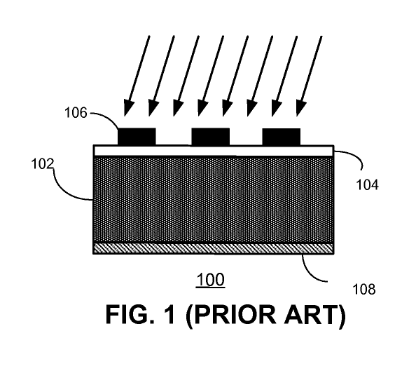

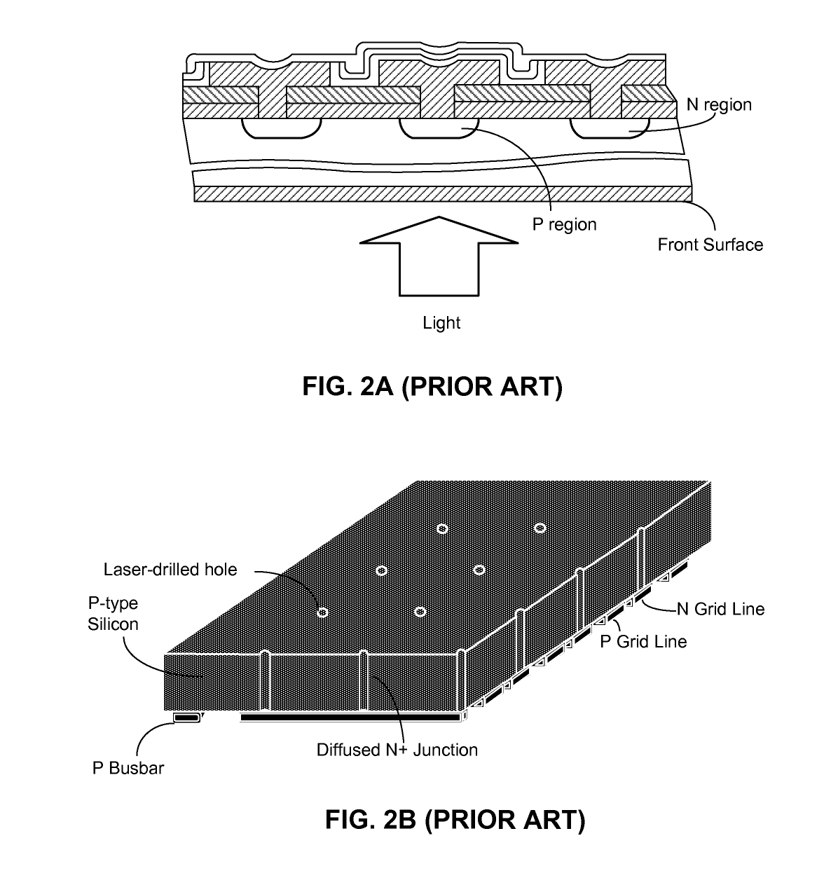

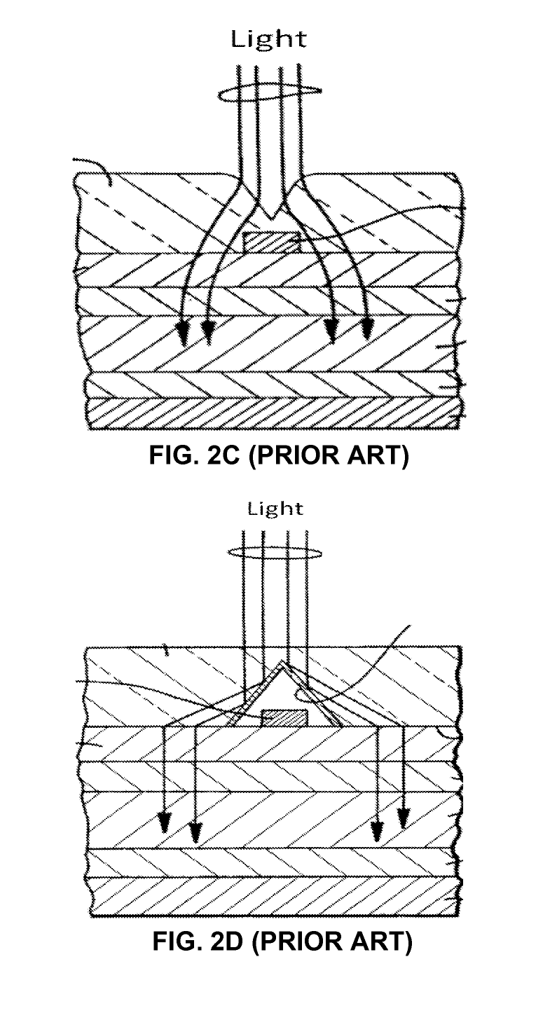

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a solar cell that includes a reflective front electrode. The reflective front electrode includes a plurality of parallel metal lines, each having a cross section with a curved perimeter. Incident light on the metal lines is reflected onto the front surface of the solar cell adjacent to the metal lines, thus significantly reducing the shading effect caused by the metal lines.

Electrode with Curved Surface

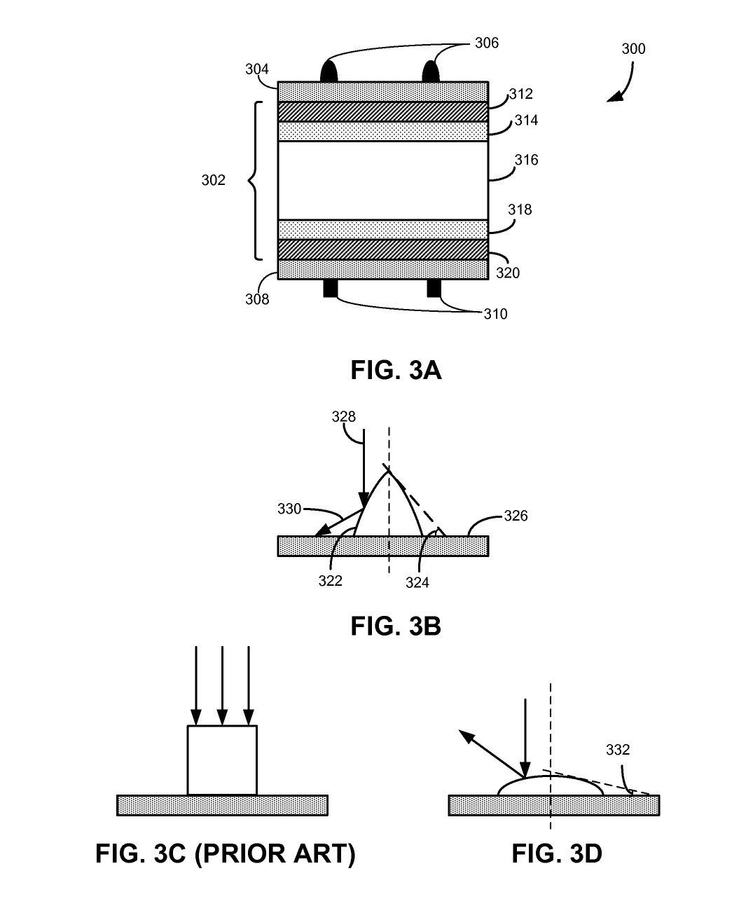

FIG. 3A presents a diagram illustrating a cross-sectional view of an exemplary solar cell that implements front metal electrode lines with curved surfaces, in accordance with an embodiment of the present invention. A solar cell 300 includes a multilayer structure 302 for converting light energy to electricity, a front-side transparent conductive oxide (TCO) layer 304 acting as a front ohmic contact, a front electrode grid 306, a back-side TCO layer 308 acting as a back ohmic contact, and a back electrode grid 310. In one embodiment, multilayer structure 302 is a double-sided heterojunction structure that includes an emitter layer 312 made of heavily doped amorphous-Si (a-Si), a front passivation layer 314 made of intrinsic a-Si, a lightly doped crystalline-Si (c-Si) base layer 316, a back passivation layer 318 made of intrinsic a-Si, and a back surface field (BSF) layer 320 made of heavily doped a-Si. Note that c-Si base layer 316 can be doped with either n-type dopant or p-type dopant. Emitter layer 312 has an opposite doping type from base layer 316, whereas BSF layer 320 has the same doping type as base layer 316. In one embodiment, emitter layer 312 and BSF layer 320 are made of graded-doped a-Si, and front and back passivation layers 314 and 318 include a thin layer of oxide, such as silicon oxide, to function as a quantum-tunneling barrier (QTB).

FIG. 3B presents a diagram illustrating a magnified view of the cross section of a front electrode grid line in accordance with an embodiment of the present invention. In this example, the curved surface of a front electrode grid line 322 has a convex shape. In one embodiment, the cross section of front electrode grid line 322 is substantially symmetric along its vertical axis, as shown in FIG. 3B. The curve that forms the cross section of front electrode grid line 322 can be of various shapes, including, but not limited to: part of a circle, part of an ellipse, part of a spiral, a parabola, a cubic plane curve, and a conchoid. The tangent plane of the curved surface of front electrode grid line 322 forms an acute angle 324 with the front surface, i.e., the surface of a front TCO layer 326, of the solar cell, as shown in FIG. 3B. Note that the two sides of angle 324 embrace front electrode grid line 322. If angle324 is greater than 45° and less than 90°, the incident light hitting the surface of grid line 322 will reflect downward to hit the surface of TCO layer 326. FIG. 3B illustrates an exemplary incident light ray 328 hitting the convex surface of grid line 322, and a reflected light ray 330 hitting the surface of TCO layer 326 and being absorbed by the solar cell. Consequently, the shading effect can be eliminated. More specifically, to ensure that incident light hitting any point on the curved surface of grid line 322 can be reflected downward, at any given point of the curved surface, the angle formed by a plane, which is tangent to the curved surface, and the solar cell surface is ideally between 45° and 90°.

FIG. 3C presents a diagram illustrating a magnified view of the cross section of a conventional front electrode grid line (prior art). From FIG. 3C, one can see that the cross section of a conventional grid line is a rectangle. Consequently, incident light hitting the grid line surface is blocked by the grid line, unable to be absorbed by the solar cell. FIG. 3D presents a diagram illustrating a magnified view of the cross section of a front electrode grid line that does not reduce or eliminate the shading effect. Similar to FIG. 3B, the front electrode grid line shown in FIG. 3D also has a convex shape. However, the acute angle formed by the solar cell surface and the tangent of the convex shape, angle 332 shown in FIG. 3D, is less than 45°. Consequently, the incident light hitting the surface of the front electrode grid line will reflect upward, as illustrated in FIG. 3D, thus not being absorbed by the solar cell.

Note that, in FIGS. 3B-3D, the incident light hits the solar cell surface and the front electrode grid line in the vertical direction. In practice, solar cells are installed outdoors to absorb sunlight, which may come from various directions depending on the season and the time of day. For example, it is more likely to have the sunlight form a vertical angle at noontime than in the morning or in the afternoon. To best utilize the sunlight and to avoid the shading effect, it is desirable to install the solar panel in such a way that the front electrode grid lines are in parallel with the latitude, and the front surface of the solar panel is tilted toward the equator at a certain angle. For example, if a solar panel is installed at 40° North Latitude, it is ideally tilted 40° toward the south.

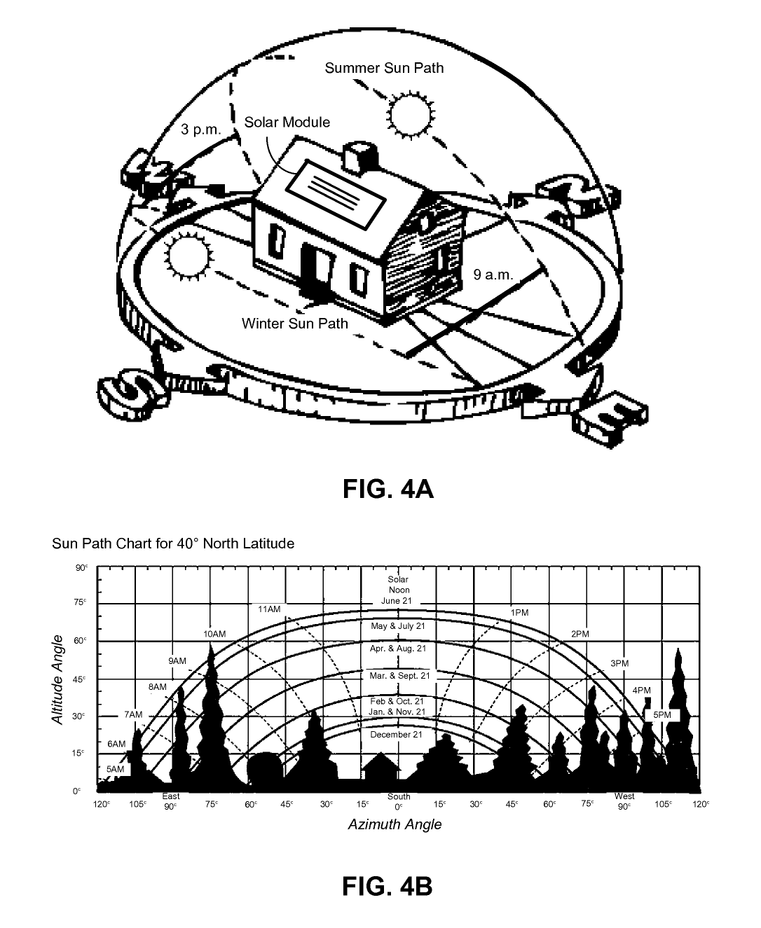

FIG. 4A presents a diagram illustrating the orientation of a solar panel installed on a rooftop in accordance with an embodiment of the present invention. The solid lines in FIG. 4A indicate the path of the sun at different times of the year, and the dotted lines indicate the location of the sun at different times of the day. FIG. 4B presents a diagram illustrating a sun path chart for a location at 40° North Latitude. As one can see from FIGS. 4A and 4B, the incident angle of the sunlight changes with the season and with the time of the day. Therefore, it is possible that, under certain circumstances, the curved surface of the front electrode grid lines may not reflect the incident sunlight downward to allow it to be absorbed by the solar cell. Although it is possible to dynamically adjust the orientation of the solar panel to maximize its sunlight absorption, such an approach is often costly and cumbersome. Hence, it is important to carefully design the curved surface of the solar cell to make sure that, regardless of the season or the time of the day, the incident sunlight hitting the grid lines can be reflected downward.

At 40° North Latitude the maximum incident angle from north in the summer is approximately 15°, and the maximum incident angle from south in the winter is approximately 45°. To minimize the shading effect for all seasons, in one embodiment of the present invention, the angle formed by the front surface of the solar cell and a plane that is tangent to the curved surface of the front electrode grid line at an arbitrary point is designed to be between 67.5° and 90°. Note that the two sides of such an angle embrace the front electrode grid line.

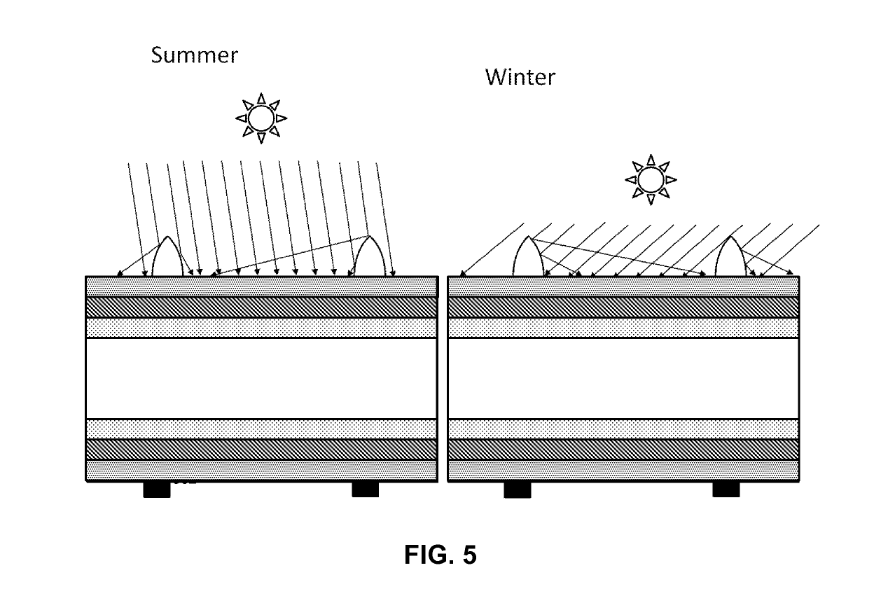

FIG. 5 presents a diagram illustrating incident sunlight reflecting off the curved surface of the grid line to be absorbed by an adjacent solar cell surface in the summer and in the winter, in accordance with an embodiment of the present invention. In the example illustrated in FIG. 5, other design criteria, such as the pitch between parallel grid lines and the height of the grid line, can also impact the amount of reflected sunlight being absorbed by the solar cell surface. Note that here the term “pitch” refers to the distance between two adjacent grid lines. In one embodiment of the present invention, the front metal grid includes parallel metal lines that form a repeated pattern. The metal lines can be straight or curved. If the pitch or the distance between the adjacent grid lines is too small, the reflected light may hit the adjacent grid line instead of the adjacent solar cell surface. On the other hand, if the pitch is too large, then the current collection efficiency of the entire grid line can be reduced. To eliminate the shading effect without negatively impacting the current collection efficiency, in one embodiment, the pitch between the parallel grid lines can be set to between 2 and 3 mm. In addition, the width of the front electrode grid lines (i.e., the width of the part of the grid line in contact with the solar cell surface) can be set to between 30 and 50 μm, and the vertical aspect ratio can be larger than 2.5.

There are various techniques for forming the front electrode grid lines with curved surfaces. In one embodiment, the metal grid lines are formed using an electroplating technique followed by a well-controlled deplating process. In a further embodiment, the metal grid lines are formed using a photoresist lift-off process. Note that, to obtain the curved surfaces for the grid lines, the sidewalls of the photoresist mask need to have an undercut profile, which can be obtained by a well-controlled photoresist developing process.

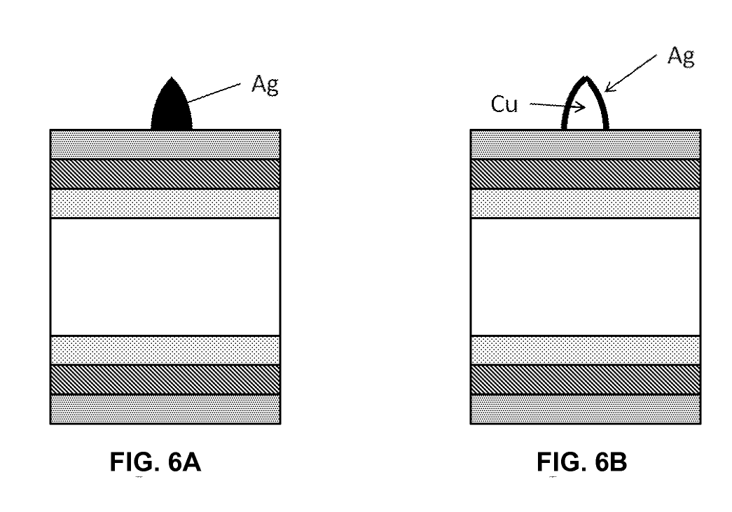

To ensure low series resistance of the front electrode grid, metals with high conductivity are chosen to form the front electrode grid. In one embodiment, front electrode grid lines are formed using Ag. FIG. 6A presents a diagram illustrating a solar cell having an Ag-based front electrode grid line in accordance with an embodiment of the present invention. In a further embodiment, front electrode grid lines are formed by coating Cu grid lines with Ag or Sn. FIG. 6B presents a diagram illustrating a solar cell having an Ag-coated or Sn coated Cu-based front electrode grid line in accordance with an embodiment of the present invention.

### Exemplary Fabrication Method

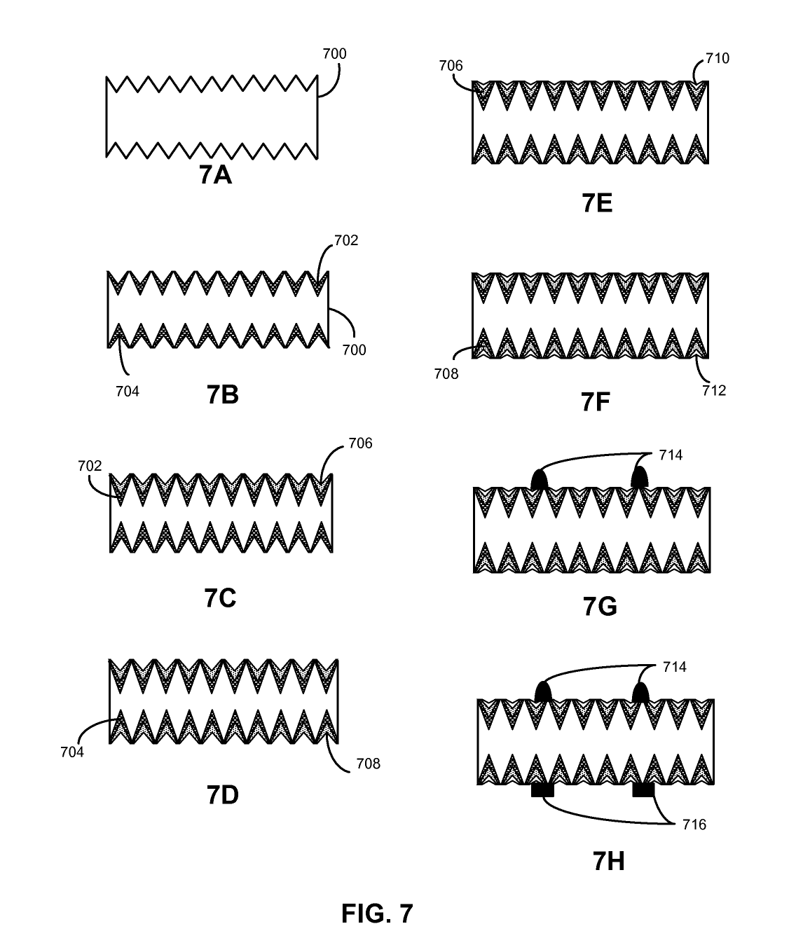

The base layer of the solar cell with shade-free front electrode can be either n-type doped or p-type doped. In addition, the base layer can be a mono-crystalline Si wafer (such as a solar-grade (SG) Si wafer) or an epitaxially formed Si thin film. In one embodiment, an n-type doped SG-Si wafer is selected as the base layer. FIG. 7 presents a diagram illustrating the process of fabricating a solar cell with shade-free front electrode in accordance with an embodiment of the present invention.

In operation 7A, an SG-Si substrate 700 is prepared. The resistivity of the SG-Si substrate is typically in, but not limited to, the range between 1 Ohm-cm and 10 Ohm-cm. It is preferable to have an SG-Si substrate with resistivity between 0.5 Ohm-cm and 10 Ohm-cm. The preparation operation includes typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation results in a random pyramid textured surface. Afterward, the SG-Si substrate goes through extensive surface cleaning.

In operation 7B, a passivation layer is formed on the front and back surfaces of SG-Si substrate 700 to form the front and back passivation layers 702 and 704, respectively. In one embodiment, only the front surface of SG-Si substrate 700 is deposited with a passivation layer. In an alternative embodiment, only the back surface of SG-Si substrate 700 is deposited with a passivation layer. Various types of dielectric materials can be used to form the passivation layer. In one embodiment, intrinsic amorphous-Si (a-Si) is used to form the passivation layer. In a further embodiment, dielectric materials, including, but not limited to: silicon oxide (SiOₓ), hydrogenated SiOₓ, silicon nitride (SiNₓ), hydrogenated SiNₓ, aluminum oxide (AlOₓ), silicon oxynitride (SiON), and hydrogenated SiON are used to form the passivation layer, which also can server as a quantum-tunneling barrier (QTB). Various deposition techniques can be used to deposit the passivation layers, including, but not limited to: thermal oxidation, atomic layer deposition, atomic oxygen, low pressure radical oxidation, plasma-enhanced chemical-vapor deposition (PECVD), etc.

In operation 7C, an emitter layer 706 is formed on top of front passivation layer 702. The doping type of emitter layer 706 is opposite from that of SG-Si substrate 700. In one embodiment, emitter layer 706 includes heavily doped a-Si. In a further embodiment, emitter layer 706 includes graded-doped a-Si. The thickness of emitter layer 706 is between 2 and 50 nm. The doping concentration of emitter layer 706 can be between 1×10¹⁵/cm³ and 5×10²⁰/cm³. The crystal structure of emitter layer 706 can be either nanocrystalline, which enables higher carrier mobility, or protocrystalline, which enables good absorption in the ultraviolet (UV) wavelength range and good transmission in the infrared (IR) wavelength range. Both crystalline structures need to preserve the large bandgap of the a-Si.

In operation 7D, a back surface field (BSF) layer 708 is formed on the surface of back passivation layer 704. The doping type of BSF layer 708 is the same as that of SG-Si substrate 700. In one embodiment, BSF layer 708 includes heavily doped a-Si. In a further embodiment, BSF layer 708 includes graded-doped a-Si. In one embodiment, the thickness of BSF layer 708 is between 3 and 30 nm. The existence of BSF layer 708 improves the back-side passivation and allows good ohmic contact with a subsequently deposited back transparent conductive oxide (TCO) layer. The doping concentration of BSF layer 708 can be between 1×10¹⁵/cm³ and 5×10²⁰/cm³. In addition to a-Si, it is also possible to use other materials to form BSF layer 708. In one embodiment, a layer of micro-crystalline Si is deposited on the surface of back passivation layer 704 to form BSF layer 708. Using micro-crystalline Si material for BSF layer 708 can ensure lower series resistance and better ohmic contact with the back TCO layer.

In operation 7E, a layer of TCO material is deposited on the surface of emitter layer 706 to form a front conductive anti-reflection layer 710. Examples of TCO include, but are not limited to: indium-tin-oxide (ITO), tin-oxide (SnOₓ), aluminum doped zinc-oxide (ZnO:Al or AZO), or gallium doped zinc-oxide (ZnO:Ga).

In operation 7F, back-side TCO layer 712 is formed on the surface of BSF layer 708.

In operation 7G, front electrode 714 is formed on top of front TCO layer 710. In one embodiment, front electrode 714 includes Ag fingers with a curved surface. In a further embodiment, front electrode 714 includes Ag-coated Cu fingers with curved surfaces. Various techniques can be used to form front electrode 714, including but not limited to: electroplating/deplating and photoresist lift-off. The tangent of the curved surface of the finger forms an angle with the horizontal surface of front TCO layer 710 that is between 67.5° and 90°. The pitch between the parallel fingers is between 2 and 3 mm; the width of the fingers is between 30 and 50 μm; and the vertical aspect ratio of the fingers is larger than 2.5.

In operation 7H, back electrode 716 is formed on the surface of back TCO layer 712. In one embodiment, back electrode 716 includes an Al finger grid, which can be formed using various techniques, including, but not limited to: screen printing of Al paste, inkjet or aerosol printing of Al ink, and evaporation.

Note that, although this disclosure gives an example of curved front electrode grid lines using the geometric configurations shown in FIGS. 3B, 5 and 6A-6B, other configurations are also possible. The shapes of the cross section of the grid lines can be different from the examples shown in FIGS. 3B, 5 and 6A-6B. For example, the cross section of the grid lines can be symmetric or asymmetric, or the perimeter of the cross section of the grid lines can have variable radiuses at different location, as long as the tangent plane at any arbitrary point on the curved surface can form an angle with the solar cell surface that is between 67.5° and 90°.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a solar cell with shade-free front electrode, comprising:
obtaining a photovoltaic body configured to convert incident light into electric energy;
forming a front-side ohmic contact layer;
forming a back-side ohmic contact layer;
forming a front-side electrode comprising a plurality of parallel metal grid lines, wherein the surface of at least one metal grid line is curved, thereby allowing incident light hitting the curved surface to be reflected downward and absorbed by the solar cell surface adjacent to the metal grid line; and
forming a back-side electrode.

2. The method of claim 1, wherein a plane tangent to the curved surface of the metal grid line forms an angle with the solar cell surface, and wherein the angle is between 67.5° and 90°.

3. The method of claim 1, wherein a pitch between the parallel metal grid lines is between 1 mm and 3 mm.

4. The method of claim 1, wherein a width of the metal grid lines is between 30 μm and 50 μm, and wherein a vertical aspect ratio of the metal grid lines is greater than 2.5.

5. The method of claim 1, wherein the metal grid lines include Ag grid lines, Ag-coated or Sn-coated Cu grid lines.

6. The method of claim 1, wherein forming the front-side electrode involves:
an electroplating process followed by a controlled deplating process; or
a photoresist lift-off process.

7. The method of claim 1, wherein obtaining the photovoltaic body comprises:
receiving a base layer that includes crystalline-Si (c-Si) of n-type doped or p-type doped;
forming a front-side passivation layer that includes intrinsic amorphous-Si (a-Si) on the front surface of the base layer;
forming a back-side passivation layer that includes a-Si on the back surface of the base layer;
forming an emitter on the front-side passivation layer, wherein the emitter includes heavily doped a-Si, and wherein the emitter has an opposite doping type of the base layer; and
forming a back surface field (BSF) layer on the back-side passivation layer, wherein the BSF layer includes heavily doped a-Si, and wherein the BSF layer has the same doping type of the base layer.

8. The method of claim 1, wherein obtaining the photovoltaic body comprises:
receiving a base layer that includes crystalline-Si (c-Si) of n-type doped or p-type doped;
forming a front-side quantum tunneling barrier (QTB) layer on the front surface of the base layer;
forming a back-side QTB layer that includes a-Si on the back surface of the base layer;
forming an emitter on the front-side QTB layer, wherein the emitter includes graded doped a-Si, and wherein the emitter has an opposite doping type of the base layer; and
forming a back surface field (BSF) layer on the back-side passivation layer, wherein the BSF layer includes graded doped a-Si, and wherein the BSF layer has the same doping type of the base layer.

9. The method of claim 8, wherein the QTB layer comprises at least one of:
silicon oxide (SiOₓ);
hydrogenated SiOₓ;
silicon nitride (SiNₓ);
hydrogenated SiNₓ;
aluminum oxide (AlOₓ);
silicon oxynitride (SiON); and
hydrogenated SiON.

10. The method of claim 1, wherein the front-side ohmic contact layer and/or the back-side ohmic contact layer include transparent conductive oxide (TCO).

11. A solar cell with shade-free front electrode, comprising:
a photovoltaic body;
a front-side ohmic contact layer situated above the photovoltaic body;
a back-side ohmic contact layer situated below the photovoltaic body;
a front-side electrode situated above the front-side ohmic contact layer, wherein the front-side electrode comprises a plurality of parallel metal grid lines, wherein the surface of at least one metal grid line is curved, thereby allowing incident light hitting the curved surface to be reflected downward and absorbed by the solar cell surface adjacent to the metal grid line; and
a back-side electrode situated below the back-side ohmic contact layer.

12. The solar cell of claim 11, wherein a plane tangent to the curved surface forms an angle with the solar cell surface, and wherein the angle is between 67.5° and 90°.

13. The solar cell of claim 11, wherein a pitch between the parallel metal grid lines is between 1 mm and 3 mm.

14. The solar cell of claim 11, wherein a width of the metal grid lines is between 30 μm and 50 μm, and wherein a vertical aspect ratio of the metal grid lines is greater than 2.5.

15. The solar cell of claim 11, wherein the metal grid lines include Ag grid lines, Ag-coated or Sn-coated Cu grid lines.

16. The solar cell of claim 11, wherein the metal grid lines are formed using one of the following processes:
an electroplating process followed by a controlled deplating process; and
a photoresist lift-off process.

17. The solar cell of claim 11, wherein the photovoltaic body comprises:
a base layer that includes crystalline-Si (c-Si) of n-type doped or p-type doped;
a front-side passivation layer that includes intrinsic amorphous-Si (a-Si) situated above the base layer;
a back-side passivation layer that includes a-Si situated below the base layer;
an emitter situated above the front-side passivation layer, wherein the emitter includes heavily doped a-Si, and wherein the emitter has an opposite doping type of the base layer; and
a back surface field (BSF) layer situated below the back-side passivation layer, wherein the BSF layer includes heavily doped a-Si, and wherein the BSF layer has the same doping type of the base layer.

18. The solar cell of claim 11, wherein the photovoltaic body comprises:
a base layer that includes crystalline-Si (c-Si) of n-type doped or p-type doped;
a front-side quantum tunneling barrier (QTB) layer situated above the base layer;
a back-side QTB layer situated below the base layer;
an emitter situated above the front-side QTB layer, wherein the emitter includes graded doped a-Si, and wherein the emitter has an opposite doping type of the base layer; and
a back surface field (BSF) layer situated below the back-side QTB layer, wherein the BSF layer includes graded doped a-Si, and wherein the BSF layer has the same doping type of the base layer.

19. The solar cell of claim 18, wherein the QTB layer comprises at least one of:
silicon oxide (SiOₓ);
hydrogenated SiOₓ;
silicon nitride (SiNₓ);
hydrogenated SiNₓ;
aluminum oxide (AlOₓ);
silicon oxynitride (SiON); and
hydrogenated SiON.

20. The solar cell of claim 11, wherein the front-side ohmic contact layer and/or the back-side ohmic contact layer includes transparent conductive oxide (TCO).

21. A solar power system, comprising:
a solar panel installed at an outdoor location with its light-absorbing surface tilted to face equator, wherein the tilted angle substantially equals the latitude of the location, wherein the solar panel comprises a plurality of solar cells, and wherein a respective solar cell comprises:
a photovoltaic body;
a front-side ohmic contact layer situated above the photovoltaic body;
a back-side ohmic contact layer situated below the photovoltaic body;
a front-side electrode situated above the front-side ohmic contact layer, wherein the front-side electrode comprises a plurality of parallel metal grid lines, wherein the surface of at least one metal grid line is curved, thereby allowing incident light hitting the curved surface to be reflected downward and absorbed by the solar cell surface adjacent to the metal grid line; and
a back-side electrode situated below the back-side ohmic contact layer.

22. The solar power system of claim 21, wherein a plane tangent to the curved surface forms an angle with the solar cell surface, and wherein the angle is between 67.5° and 90°.

23. The solar power system of claim 21, wherein a pitch between the parallel metal grid lines is between 1 mm and 3 mm.

24. The solar power system of claim 21, wherein a width of the metal grid lines is between 30 μm and 50 μm, and wherein a vertical aspect ratio of the metal grid lines is greater than 2.5.

25. The solar power system of claim 21, wherein the metal grid lines include Ag grid lines, Ag-coated or Sn-coated Cugrid lines.

26. The solar power system of claim 25, wherein the metal grid lines are formed using one of the following process:
an electroplating process followed by a controlled deplating process; and
a photoresist lift-off process.
